(19) United States
(12) Patent Application Publication
(10) Pub. No.: US 2009/0310786 A1
(43) Pub. Date: Dec. 17, 2009

(54) Systems for Channel Coordination of Audio and Data Transmission in a Broadcast Band

(75) Inventors: Yifeng Zhang, San Jose, CA (US); Victor Ren, Fremont, CA (US); Bo Xia, SanJose, CA (US)

Correspondence Address: Blairtech Solution LLC, 1039 Merritt Terrace, Sunnyvale, CA, 94086, US

(73) Assignee: QUINTIC HOLDINGS, Santa Clara, CA (US)

(21) Appl. No.: 12/495,796

(22) Filed: Jun. 30, 2009

Related U.S. Application Data
(63) Continuation-in-part of application No. 12/137,535, filed on Jun. 11, 2008.

(51) Int. Cl. H04K 1/00; H04L 27/00; H03K 7/06; H04L 27/02

(52) U.S. Cl. 380/270; 375/259; 375/271; 375/268

(57) ABSTRACT

Systems for audio and data transmission in a broadcast band are disclosed. The system comprises a channel condition assessment module at the transmit side to identify an un-occupied or empty channel to transmit. The system also comprises a means to achieve automatic channel coordination between the transmit side and the receive side. Further, the transmit side includes a digital interface module and the receive side includes a digital output interface module configured to control an embedding electronic device. Means for enhancing audio privacy and digital data rate are also disclosed.

### CROSS REFERENCE TO RELATED APPLICATIONS

The present invention is related and claims priority to U.S. Non-Provisional patent application Ser. No. 12/137,535, filed Jun. 11, 2008, entitled “Frequency Modulation (FM) Clear Channel Scanning System and Method of Using Same,” U.S. Non-Provisional patent application Ser. No. 12/172,147, filed Jul. 11, 2008, entitled “Channel Coordination between a Wireless Earphone and a Transmitter,” and U.S. Non-Provisional patent application Ser. No. 12/473,281, filed May 28, 2009, entitled “Radio Transmitter and Radio Receiver with Channel Condition Assessment”. These U.S. Non-Provisional patent applications are hereby incorporated by reference in their entireties

### FIELD OF THE INVENTION

The present invention generally relates to radio transmitters and radio receivers and particularly to audio and data transmission in an FM broadcast system.

### DESCRIPTION OF THE PRIOR ART

FM (Frequency Modulation) radio transmitter has been widely used in portable devices such as cellphone, MP3 (MPEG-1 Audio Layer 3) player, PDA (Portable Digital Assistant), and PMP (Portable Media Player) to output audio contents on the device to an external FM radio receiver. The FM radio provides an instant wireless audio link between the portable device and the FM audio receiver that is available almost everywhere worldwide. This wireless link allows a user to playback the audio contents onto the FM radio receiver in a car for driving safety. Also a user may enjoy the better audio quality usually available in a car or home radio receiver. The FM radio transmitter may comply with the worldwide FM audio broadcast standard (for example, the FM broadcast system in US occupying a nominal spectrum from 87.5 to 108 MHz or any other similar FM systems). The radio transmitter may also be an AM (Amplitude Modulation) system that complies with the worldwide AM audio broadcast system (for example, the AM broadcast system in US occupying the nominal spectrum from 520 to 1710 kHz, other similar AM systems, or other broadcast bands such as SW and MW.

On the other hand, FM radio receiver is even more widely used in portable devices such as cellphone, MP3, PDA, and PMP. The FM radio receiver provides a user the convenience to enjoy FM radio listening experience anywhere anytime. Paired with a portable device equipped with an FM transmitter, the portable devices may share audio contents among them. In another application, the FM receiver may be used as a wireless earphone to be paired with a portable device equipped with an FM transmitter.

In the radio transmitter application, scanning and finding an unoccupied or vacant channel for transmission and avoiding interference with a licensed broadcast channel or other undesirable channels is highly desirable in an effort to increase efficiency and quality and to take advantage of such available channels. If the selected channel for transmission is also being used by a local broadcast radio station, the transmission from the portable device will interfere with the signal being transmitted from the local radio station. This will result in poor reception quality of the signal from the portable device, or otherwise the portable device may have to transmit at a much higher power level to “over-power” the local radio station which may interfere with the intended reception of the local radio and may violate the regulatory compliance. Consequently, it is extremely important to scan for an unoccupied channel before the portable device starts to transmit.

In the U.S. Non-Provisional patent application Ser. No. 12/137,535, filed Jun. 11, 2008, entitled “Frequency Modulation (FM) Clear Channel Scanning System and Method of Using Same,” a reliable and fast clear-channel-scan (CCS) method and system are described. In the U.S. Non-Provisional patent application Ser. No. 12/172,147, filed Jul. 11, 2008, entitled “Channel Coordination between a Wireless Earphone and a Transmitter,” a method and system of automatic coordination between a wireless transmitter and earphone is described. The FM broadcast band is commonly available in most regions worldwide and can be used for applications beyond the originally intended audio broadcasting. Such applications may include wireless remote control based on the FM broadcast band, audio broadcast with high-rate data service, and secure wireless voice communication. The current Radio Broadcast Data System (RBDS) or the Radio Data System (RDS) along with the associated FM audio broadcast does not address the needs of the above mentioned applications. For example, in the wireless remote control application, the required data rate is very low and however, it is more important to achieve high reliability than high data rate for such application. The bandwidth allocated for the RBDS/RDS standard uses small frequency deviation to carry the underlying data. Therefore, the integrity of transmitted data is often compromised. In FM broadcast application, there are cases where high-fidelity stereo audio is non-essential while high data rate transmitted in the side channel is very desirable. Traffic message channel is good example of such application where the digital data may carry local traffic updates including events, locations, and clock. Currently, RBDS or RDS only allocates a data rate about 1.1875 Kbits per second for each FM channel. This data rate is too slow for the traffic message application in metropolitan areas where the traffic condition is fairly complex and requires much higher data rate to carry real-time traffic information, or other high data applications.

In the radio transmit and receive applications, where both transmitter and receiver can be designed to accommodate needed features that the standard FM broadcast system does not offer. Such features may include privacy for the underlying audio signal, automatic channel coordination between receivers and a transmitter, automatic channel following in a mobile environment, and high-rate digital data with or without associated audio.

In light of the foregoing discussions, the need arises for providing reliable and/or high data rate services using the existing FM broadcast band. Furthermore, there is also a need for providing secure audio transmission along with the digital data in the broadcast band that everyone can listen into the channels.

### BRIEF SUMMARY OF THE INVENTION

The present invention discloses a system for remote control using an FM broadcast band. The remote control transmitter unit comprises a channel condition assessment module to identify a best channel to transmit. The remote control transmitter unit then transmits digital data at the channel identified. On the other end of the wireless channel, an FM receiver is configured to receive radio signals in the band. The FM receiver identifies the channel having the digital data and receives the digital data. The received digital data can then be used by the receiver end for intended applications such as controlling sound volume of an electronic device embedding the present invention.

The present invention also discloses an FM data transmission system using an FM broadcast band. At the transmit side, a first device is used to accept digital data and an FM transmitter having a channel condition assessment module to identifies a channel transmits the digital data using the identified channel. At the receive end, an FM receiver is configured to receive radio signals in the band. The FM receiver identifies the channel having the digital data and receives the digital data. The received digital data is provided to a second device and the settings associated with the second device are controlled according to the received digital data. In one embodiment of the current invention, a user ID is used for automatic coordination between the FM receiver and the FM transmitter.

The present invention further discloses an FM audio and data transmission system using an FM broadcast band. At the transmit side, a first device is used to accept digital data and an audio interface module is configured to provide audio signal. An FM transmitter identifies an empty channel, where the channel includes a main channel and a side channel, and transmits the digital data at the side channel and the audio signal at the main channel. At the receive end, an FM receiver is configured to receive radio signals in the band. The FM receiver identifies the channel having the digital data in the side channel and receives the digital data in the side channel and the audio signal in the main channel. The received digital data is provided to a second device and the settings associated with the second device are controlled according to the received digital data. In one embodiment of the present invention, the audio is encrypted by an audio encryption module using an audio encryption key at the transmit side and decrypted by an audio decryption module using a decryption key at the receive side. The decryption key can be either stored at the receive side or recovered from the transmitted digital data using a user ID where the user ID is stored at the receive side. The encryption/decryption can be implemented using either a digital technique or an analog technique.

In another embodiment, the present invention discloses an FM audio and data transmission system using an FM broadcast band. At the transmit side, a first device is used to accept digital data and an audio interface module is configured to provide audio signal. An FM transmitter, having a channel condition assessment module to identify a channel having a main channel and a side channel, transmits the digital data at the side channel and the audio signal at the main channel. At the receive end, an FM receiver is configured to receive radio signals in the band. The FM receiver identifies the channel having the digital data in the side channel and receives the digital data in the side channel and the audio signal in the main channel. The received digital data is provided to a second device and the settings associated with the second device are controlled according to the received digital data.

Furthermore, the current invention allocates a digital data bandwidth other than the bandwidth defined in RDS/RBDS standard so that a different data rate service can be provided for FM audio and data transmission systems.

### BRIEF DESCRIPTION OF THE DRAWINGS

FIG. 1 shows the spectrum of an FM stereo broadcast system with RDS/RBDS and other side channel data.

FIG. 2 shows the spectrum of an exemplary FM audio with high-speed digital data channel for the present invention.

FIG. 3 shows a block diagram of an exemplary channel condition assessment module.

FIG. 4 shows a block diagram of a wireless remote control system comprising a transmit unit and a receive unit.

FIG. 5A shows an exemplary remote control system based on the FM broadcast band comprising a remote control and an electronic device having an embedded remote control receiver.

FIG. 5B shows a sample block diagram of a remote control system.

FIG. 6 shows an exemplary FM audio and data broadcast system comprising an audio and digital data transmitter unit and an electronic device having an embedded FM audio and digital data receiver.

FIG. 7 shows a block diagram of an FM audio and digital data transmitter unit where an audio encryption module is included.

FIG. 8 shows a block diagram of an FM audio and digital data receiver unit where an audio decryption module is included.

FIG. 9 shows an exemplary FM audio and data broadcast system comprising an audio and digital data transmitter unit having a channel condition assessment module and an electronic device having an embedded FM audio and digital data receiver unit.

### DETAILED DESCRIPTION

In the following description, numerous details are set forth to provide a more thorough explanation of embodiments of the present invention. It will be apparent, however, to one skilled in the art, that embodiments of the present invention may be practiced without these specific details. In other instances, well-known structures and devices are shown in block diagram form, rather than in detail, in order to avoid obscuring embodiments of the present invention.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams representing one or more embodiments of the invention do not inherently indicate any particular order nor imply any limitations in the invention.

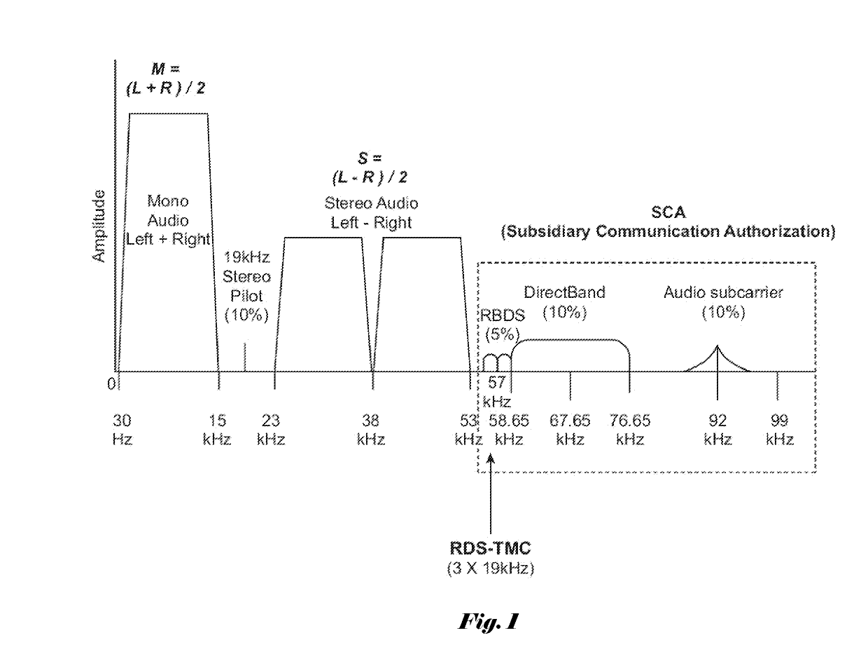

Embodiments of the present invention are discussed herein with reference to FIGS. 1 to 9. However, those skilled in the art will readily appreciate that the detailed description given herein with respect to these figures is for explanatory purposes as the invention extends beyond these limited embodiments.

Although the present invention has been described in terms of specific embodiments it is anticipated that alterations and modifications thereof will no doubt become apparent to those skilled in the art. It is therefore intended that the following claims be interpreted as covering all such alterations and modification as fall within the true spirit and scope of the invention.

In U.S. Non-Provisional patent application Ser. No. 12/137,535, filed Jun. 11, 2008, entitled “Frequency Modulation (FM) Clear Channel Scanning System and Method of Using Same” and U.S. Non-Provisional patent application Ser. No. 12/473,281, filed May 28, 2009, entitled “Radio Transmitter and Radio Receiver with Channel Condition Assessment”, channel condition assessment methods and systems are described as a means to identify an un-occupied or empty channel. A channel so identified is free from noticeable interference and can be used to deliver high quality audio or/and digital data transmission.

In a conventional FM broadcast system, the baseband signal spectrum is shown in FIG. 1 where the horizontal axis represents the frequency in kilo-Hertz (kHz) and the vertical axis represents the amplitude of the signal. The conventional FM broadcast signal is designed mainly for high-quality stereo audio signals. In order to be compatible to previously existing mono FM audio broadcast system, the stereo audio signals, represented as a left channel (L) audio signal and a right channel (R) audio signal, are multiplexed into (L+R)/2 signal and (L−R)/2 signal. The (L−R)/2 signal is transmitted using a subcarrier signal at 38 kHz. The RDS/RBDS digital data is transmitted using a subcarrier signal at 57 kHz. As shown in the FIG. 1, the frequency deviation allocated to RDS/RBDS is much lower than the audio signal. The digital data rate available from RDS/RBDS data system is roughly 1.1875 Kbits per second. Other than RDS/RBDS data, there are also other digital data channels used for subsidiary communication purposes or other purposes. In this specification, the main audio channel ((L+R)/2), the sub-audio channel ((L−R)/2), and the stereo pilot signal collectively are designated as the main channel. For any sub-channel other than the main audio channel is designated as a side channel.

While the conventional standard FM broadcast system can satisfy the application of FM stereo audio broadcasting, it may not fulfill the needs for personal wireless earphone, wireless telephone, or FM audio broadcast with high-rate data. In these applications, the underlying audio may be voice which has signal spectrum primarily under 4 kHz and the conventional FM broadcast system would be wasteful for such applications. For the personal wireless earphone or wireless telephone applications, the privacy of the underlying voice is often a concern. However, the conventional FM broadcast system does not address the privacy issue at all.

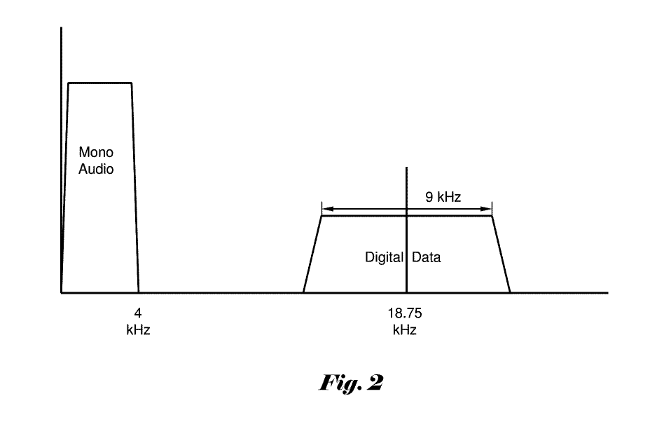

The standard FM broadcast system accommodates digital data broadcast via RDS/RBDS transmitted at side channel within the channel. The data carried in RDS/RBDS can be used to deliver various types of service information such as metadata associated with the music, clock, weather, traffic, and etc. However, the data service is primarily for static service where the information flow is small. For the traffic message service, particularly in metropolitan areas where the data volume may be very high, the digital data rate available through RDS/RBDS may not be sufficient. Accordingly, a new spectrum allocation, as shown in FIG. 2, is designed to fulfill the needs mentioned above. FIG. 2 shows that the audio bandwidth allocated is about 4 kHz which is enough to deliver high quality for voice. The bandwidth allocated for digital data is about 9 kHz and the center for digital data is located at 18.75 kHz. In order to improve the modulation efficiency, the 18.75 kHz carrier signal for the digital data signal is suppressed.

The digital data carried in the side channel can be used to coordinate automatic pairing between an FM transmitter and an FM receiver equipped with the auto-pairing capability. In the U.S. Non-Provisional patent application Ser. No. 12/172,147, filed Jul. 11, 2008, entitled “Channel Coordination between a Wireless Earphone and a Transmitter,” systems and methods of channel coordination between a wireless earphone and an FM transmitter are disclosed. The wireless earphone device includes an FM receiver with an RDS or RDBS receiver and an audio decryption module, and the FM transmitter unit includes an FM transmitter with RDS and audio encryption capability. The wireless earphone device automatically tunes to a vacant channel found by the FM transmitter unit without or with minimum human intervention and in real-time thereby allowing the process of tuning and receiving audio signals through the wireless earphone device transparent to the user of the wireless earphone device.

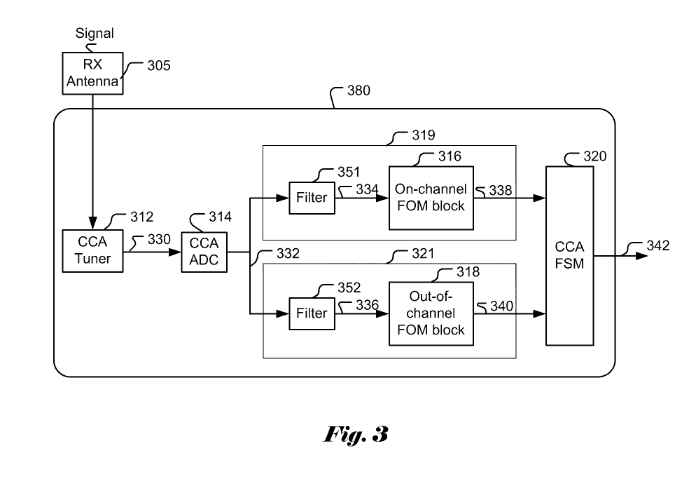

Though the signal spectrum for the current invention is different from the conventional FM broadcast system, they all share the same FM broadcast band. Therefore, it is important to identify a channel not being used by a conventional FM broadcast signal or any other signal transmitted at the channel. In the US Non-Provisional patent application Ser. No. 12/137,535, filed Jun. 11, 2008, entitled “Frequency Modulation (FM) Clear Channel Scanning System and Method of Using Same,” reliable and fast clear-channel-scan methods and systems are described and can be used in the current invention as well. FIG. 3 shows a block diagram of the scan system 380 in accordance with an embodiment of the present invention. The scan system 380 is shown to include channel condition assessment (CCA) tuner 312, CCA analog-to-digital converter (ADC) 314, filter 351, filter 352, on-channel Figure of Merit (FOM) block 316, out-of-channel FOM block 318 and CCA finite state machine (FSM) 320. RX Antenna 305 as shown is coupled to scan system 380. The RX Antenna 305 is coupled to the CCA tuner 312. The CCA Tuner 312 is coupled to the CCA ADC 314 via signal line 330. The CCA ADC 314 is coupled to both the filter 351 and the filter 352. The filter 351 is coupled to the on-channel FOM block 316. The on-channel FOM block 316 is coupled to the CCA FSM 320 through signal line 338. The filter 352 is coupled to the out-of-channel FOM block 318. The out-of-channel FOM block 318 is shown coupled to the CCA FSM 320 via signal line 340. When using the scan system 380 in an FM broadcast band, the CCA tuner 312 operates as an FM tuner. When using the scan system 380 in an AM band application, the tuner 312 operates as an AM tuner.

The filter 351 and the on-channel FOM block 316 collectively comprise the on-channel selection block 319. In some embodiments, the filter 351 and the on-channel FOM block 316 are physically the same block and in other embodiments they may appear, as shown in FIG. 3, as separate structures. The filter 352 and the out-of-channel FOM block 318 collectively comprise the out-of-channel selection block 321. In some embodiments, the filter 352 and the out-of-channel FOM block 318 are physically the same block and in other embodiments they may appear as separate structures as shown in FIG. 3.

RX Antenna 305 is shown to receive signals, in the form of an analog signal, and to transmit the same to the tuner 312. Tuner 312 receives the analog signal is operative to select a single station by excluding substantially all others and to generate a tuned analog signal 330 for use by the CCA ADC 314. Tuner 312 is user-programmable to select a start and stop frequency range and a step frequency and in this manner divides the band into multiple sub-bands when desired.

In an exemplary embodiment, the selected step frequency is 200 kHz and the band is divided into sub-band. The CCA ADC 314 is operative to receive the signal 330 and to convert the same to digital signal 332. The signal 332 is then coupled onto filter 351 and filter 352. Filter 351 is designed to select substantially only the on-channel frequencies and to substantially disregard the out-of-channel frequencies from the signal 332 to generate the on-channel signal 334. Filter 352 is operative to select substantially only the out-of-channel frequencies and to substantially disregard the on-channel frequencies from the signal 332 to generate the out-of-channel signal 336.

The filter 351 is further operative to transfer the on-channel signals 334 to the on-channel FOM block 316. The on-channel FOM block 316 is operative to measure the FOM of the on-channel signals 334 (a measurement representing the measurement of signal quality of the on-channel signal), and the out-of-channel FOM block 318 is operative to measure the out-of-channel signals 336 (a measurement representing the measurement of signal quality of the out-of-channel signal). The CCA FSM 320 is operative to determine an unoccupied or empty channel and information associated with the selected channel is provided via signal line 342.

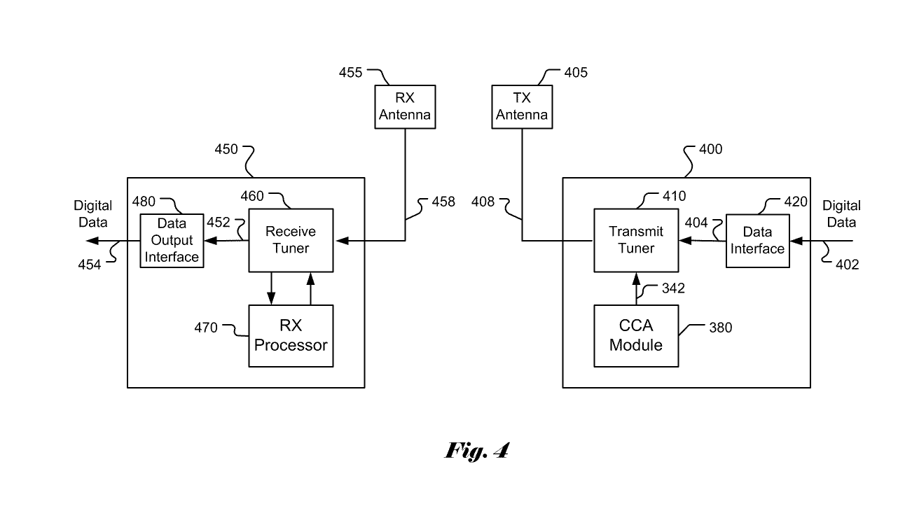

FIG. 4 shows one embodiment of the current invention in a remote control system. The transmit unit 400 accepts digital data through the external signal line 402 and the digital data is transmitted by the transmit tuner 410 which is considered as part of an FM transmitter. To select an unoccupied or empty channel, the transmit unit 400 includes a CCA module 380 that provides information about the unoccupied or empty channel through signal line 342. The CCA module 380 is also considered as part of the FM transmitter. The transmit tuner 410 is known by people skilled in the art which may include an FM modulator, mixer, local oscillator (LO), filters, and power amplifier. The signal output 408 from transmit tuner 410 is radiated from the TX antenna. The CCA module 380 receives signals in the FM broadcast band in order to assess channel condition. The antenna for the CCA module 380 to receive signal is not shown in the figure. However, it is understood that there is a CCA receive antenna provided and the CCA receive antenna may share the same antenna 405 with the transmit antenna tuner 405.

The data interface module 420 accepts digital data from signal line 402. Depending on the application, the data interface module 420 may simply pass the digital data input 402 to digital data output 404. However, in many applications, the data interface module will format the digital data input arrived at line 402 to make it suitable for transmission in the FM broadcast channel. The formatting may include forward error correction (FEC), padding with data delimiter, data tagging for identifying data type, and data insertion such as a user ID. The above are exemplary functions associated with the data interface module 420. Other functions may also be included such as data scrambling for privacy and data conversion for compact data representation.

The receive unit 450 receives signals from RX antenna 455 in the FM broadcast band. The receive tuner 460 receives antenna signal 458 and performs FM receiving function and may include low-noise-amplifier (LNA), filters, mixer, LO, and FM demodulator. Unlike a conventional FM broadcast receiver where a user selects a channel or uses automatic channel search to tune to a next valid channel, the receive unit 450 needs to identify the channel that carries the intended digital data. An RX processor 470 is considered as part of the FM receiver and the RX processor 470 examines the signals received and identifies the channel containing the intended digital data. The RX processor 470 is coupled with the receive tuner 460 to manage the procedure of searching for the channel. When the desired channel is identified, the receive tuner 460 receives the digital data and provides the received digital data 452 it to the data output interface module 480. The data output interface module 480 processes the digital data 452 and outputs it through signal line 454. The data output interface module 480 is a counterpart of the data interface module 420 and performs inverse functions to undo the process by the data interface module 420.

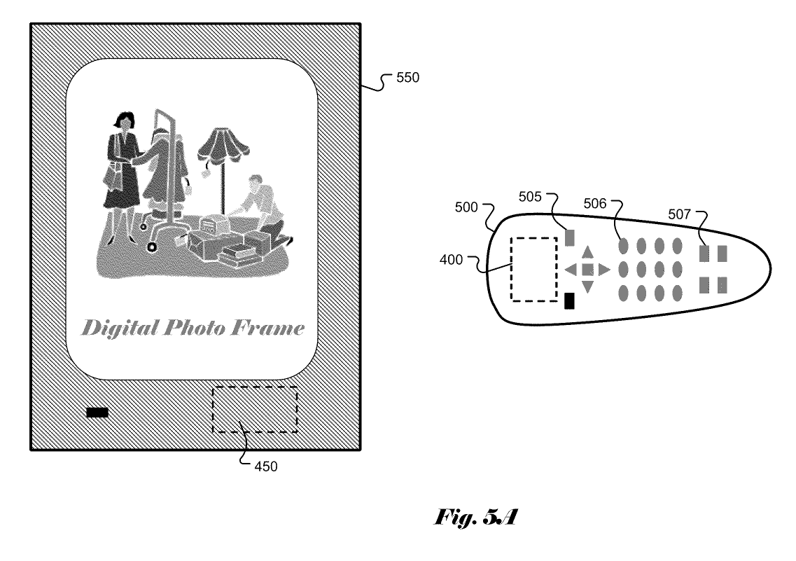

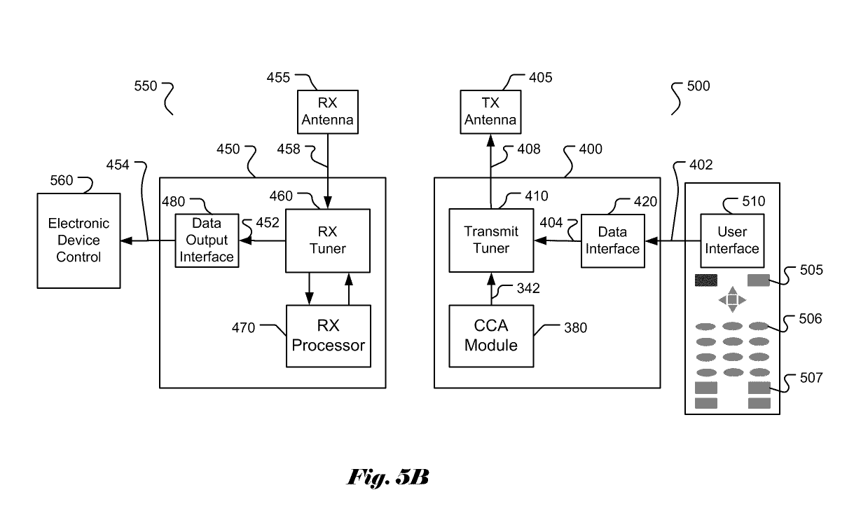

FIG. 5A shows another exemplary remote control and an electronic device embodying the present invention. The remote control 500 comprises the transmit unit 400 and a plurality of buttons 505-507 to allow a user to enter selection or command. The remote control may also include an LCD display to confirm the selection or command entered by the user. The remote control also includes a TX antenna required for FM transmission. The TX antenna can be an external antenna such as a pull-up antenna or a wire antenna. However, an internal antenna such a PCB antenna or a wire antenna may also be used for convenience and compactness. The CCA module 380 inside the transmit unit 400 also requires an RX antenna which can be either a dedicated antenna or a shared antenna with the TX antenna.

The electronic device illustrated in this exemplary application represents a digital photo frame containing a receive unit 450. Other electronic devices such as television set, portable media player (PMP), multimedia gateway, and cordless phone may also be benefited by the present invention. The digital photo frame may provide a plurality of settings for a user to control. The settings may include, for example, photo navigation and display control, and power on/off. The LCD display of the digital photo frame may also be used to display setting options as on-screen-display (OSD) for convenient user interface. The RX antenna required by the receive unit 450 is not shown explicitly. However it is understood that an RX antenna is either embedded as an internal antenna or included as an external antenna in the digital photo frame 550. In typical digital photo frame applications, the device will use a power adaptor instead of batteries for extended use. The wire used by the power adaptor may be used as the antenna for the receive unit 450 by properly coupling the RF signal pickup up by the wire of the power adaptor to the input of the RX tuner 460. The coupling will require tuning circuits as is well known by those skilled in the art.

FIG. 5B shows a sample block diagram corresponding to the remote control 500 and the electronic device 550. The remote control 500 comprises a transmit unit 400, a TX antenna 405, a user interface module 510 and a plurality of buttons 505-507. The user interface module 510 detects any button being pressed and converts the operation of buttons into a digital data 402 corresponding to user selection or command. The digital data 402 corresponding to the user selection or command is send to the data interface module 420. The electronic device 550 embodying the present invention comprises the receive unit 450, an RX antenna 455, and an electronic device control 560. Only the control module 560 for the electronic device is shown and other portions associated with the electronic device are not shown because they are not directly relevant to the present invention.

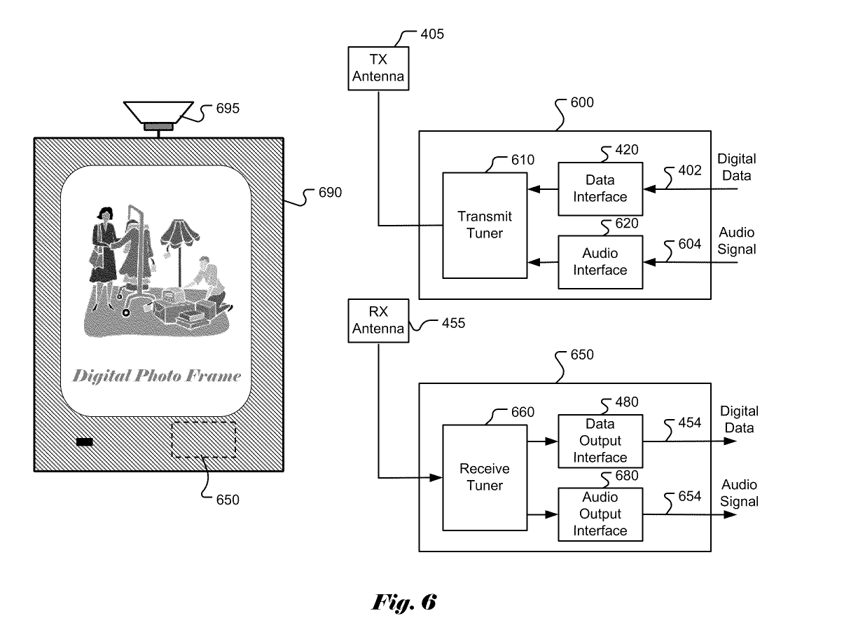

FIG. 6 shows yet another system embodying the present invention where both audio and digital data are delivered by the FM radio. The system includes a transmit unit 600, and a receive unit 650 and associated antennas 405 and 455. The exemplary application embodying a receive unit 650 of the present invention is a digital photo frame 690 having audio capability with a speaker 695. While a digital photo frame is used as a sample electronic device, other electronic devices such as television set, portable media player (PMP), multimedia gateway, and cordless phone may also be benefited by the present invention. The transmit unit 600 comprises a data interface module 420, an audio interface module 620 and a transmit tuner 610 where the transmit tuner 610 is capable of carrying both audio and digital data. The data interface module 420 accepts digital data from signal line 402 and the audio interface module 620 accepts audio signal from audio signal line 604. The receive unit 650 comprises a receive tuner 660, a data output interface module 480, and an audio output interface module 680. The data output interface module 480 provides the received digital data 454 and the audio output interface module 680 provides the received audio signal 654.

The digital photo frame 690 may provide a plurality of settings for a user to control the electronic device. The settings may include, for example, photo navigation and display control, power on/off, and volume control of associated audio. The LCD display of the digital photo frame may also be used to display setting options as on-screen-display (OSD) for convenient user interface. Also, the received digital data by the receive unit 650 may be displayed on the LCD of the digital photo frame 690. Furthermore, the digital photo frame may include a standard FM receiver to receive the FM stereo audio and associated RDS/RBDS data. These data may include metadata associated with a song, program type, station ID, clock, weather, and traffic information, and can be conveniently displayed on the LCD screen of the digital photo frame 690. The RX antenna 455 required by the receive unit 650 is not shown explicitly. However it is understood that an RX antenna is either embedded as an internal antenna or included as an external antenna in the digital photo frame 690. When the digital photo frame 690 also includes a standard FM receiver for receiving the conventional FM broadcast signal, the receive unit 650 may easily accommodate the conventional receiving function for FM broadcast signal with a minimum cost increase. The additional advantage of using the FM broadcast based remote control is apparent.

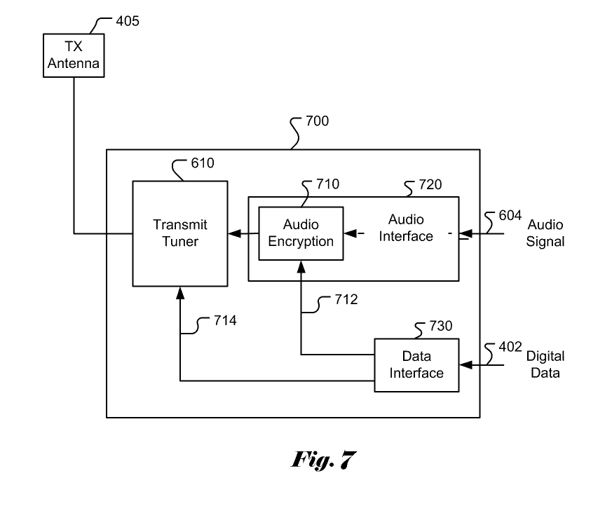

In one exemplary embodiment of the present invention, the system can be used to provide privacy for the underlying audio. The transmit side is shown in FIG. 7 which comprises a transmit unit 700 and a TX antenna 405. The transmit unit 700 comprises a transmit tuner 610, a data interface module 730 and an audio interface module 720 which includes an audio encryption module 710. While the audio encryption module 710 is shown as part of the audio interface module 720, the audio encryption module 710 may also be a separate module inside the transmit unit 700 or combined with other blocks of the transmit unit 700. As shown in this exemplary implementation, the encryption key 712 for the audio encryption device 710 is provided by the data interface module 730, however, the encryption key may be provided by a separate block in the transmit unit 700 or combined with other blocks of the transmit unit 700. The audio interface module 720 may also include other functions in addition to audio encryption, such as audio signal analog-to-digital conversion, digital-to-analog conversion, or data formatting depending on applications. The audio encryption can be an analog approach or a digital approach. The analog approach may include spectrum inversion and the implementation may be done digitally. The digital approach may be applied to compressed or un-compressed digital audio and there are many well known digital encryption techniques such as DES and AES. If digital encryption is adopted, the compressed digital audio is preferred because it conserves bandwidth and is more suited for the intended application. The encryption key for the audio encryption module 710 may be pre-store in the transmit unit 700. The encryption key may also be provided externally through the digital data line 402.

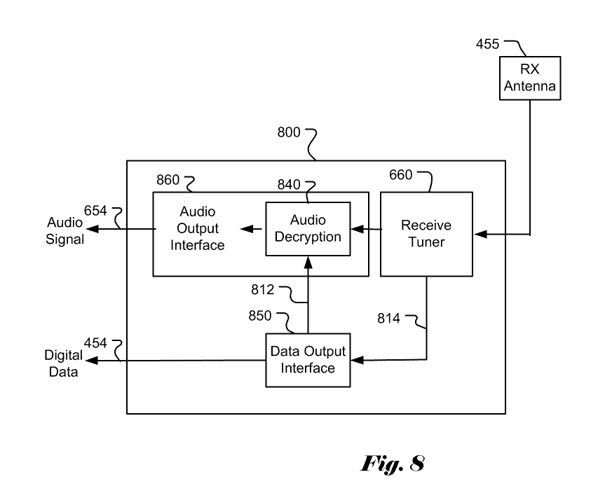

The receive side corresponding to the transmit unit 700 with antenna 405 is shown in FIG. 8 which comprises an RX antenna 455 and a receive unit 800. The receive unit 800 comprises a receive tuner 660, an audio output interface module 860 and a digital output interface module 850. As shown in FIG. 8, the audio output interface module 860 includes an audio decryption module 840 to descramble received audio signal. Nevertheless, the audio decryption module 840 may be implemented as a separate block in the receive unit 800 or combined with other blocks of the receive unit 800. The correct operation of the audio decryption relies on a decryption key 812 matched to the encryption key at the transmit side. As shown in the exemplary implementation, the decryption key 812 is provided by the data output interface module 850. However, the decryption key 812 may also be provided by separate block of the receive unit 800 or may be pre-assigned and stored in a memory device at the receive unit 800. In some applications, the decryption key may be transmitted as part of digital data and the decryption key usually is scrambled for protection from unauthorized reception. For example, the decryption key may be scrambled using a user ID which is made available or known to the receive unit 800. In the exemplary implementation, the data output interface module 850 receives the transmitted digital data 814 and provides the decryption key 812 to the audio decryption module 840 and the digital data 454 as data output. When the decryption key is scrambled, the data output interface module 850 is responsive to descramble the decryption key. However, the key descramble function may also be implemented as a separate block of the receive unit 800 or combined into other blocks of the receive unit 800. The original digital data may be processed by the data interface module 730, and the data output interface module 850 is configured to reverse the processing done by the data interface module 730. For example, if the digital data is FEC protected by the transmit unit 700, the data output interface module 850 will perform FEC decoding to recover the original digital data.

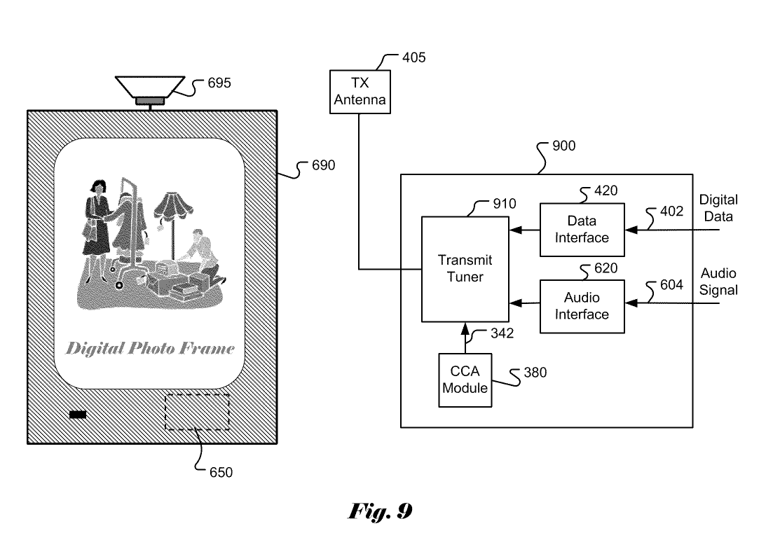

FIG. 9 illustrates another embodiment of the present invention containing a CCA module 380 at the transmit side. The transmit unit 900 is similar to the transmit unit 600 except that the transmit tuner 910 is coupled to the CCA module 380 through signal line 342. The same receiving electronic device 690 as that of FIG. 6 can be used to receive signal transmitted by the transmit unit 900.

In accordance with the various embodiments of the present invention, a radio transmit system and a radio receive system incorporating the scan system are disclosed. The systems are partitioned into various component blocks to fulfill the required processing. However, it is understood by a skilled person in the art that there are many different ways to partition a radio transmit system or a radio receive system to achieve the same goal.

What is claimed is:

1. A system, comprising:
a transmit unit; and
a receive unit,
wherein the transmit unit includes
a data interface module configured to accept a first digital data and to provide a second digital data, and
a transmit tuner using a frequency band coupled to the data interface module to accept said second digital data, wherein the transmit tuner having a channel condition assessment module to identify a channel and transmitting said second digital data at the channel; and
wherein the receive unit includes
a receive tuner configured to receive a signal corresponding to a plurality of the channels in the frequency band, wherein the receive tuner is operable to identify the channel having said second digital data and to receive said second digital data, and
a data output interface module coupled to the receive tuner to accept said second digital data and provide said first digital data.

2. The system of claim 1, wherein said second digital data transmitted by the transmit tuner includes a user ID.

3. The system of claim 2, wherein the receive unit includes a non-volatile memory to store the user ID.

4. The system of claim 3, wherein the receive tuner identifies the channel having said second digital data according to the user ID.

5. The system of claim 1, wherein the frequency band is an FM broadcast band.

6. The system of claim 1, wherein the frequency band is an AM broadcast band.

7. A system, comprising:
a transmit unit; and
a receive unit,
wherein the transmit unit includes
a first device configured to provide a first digital data,
a data interface module coupled to the first device to accept said first digital data and to provide a second digital data, and
a transmit tuner using a frequency band coupled to the data interface module to accept said second digital data, wherein the transmit tuner having a channel condition assessment module to identify a channel and transmitting said second digital data at the channel; and
wherein the receive unit includes
a receive tuner configured to receive a signal corresponding to a plurality of the channels in the frequency band, wherein the receive tuner is operable to identify the channel having said second digital data and to receive said second digital data,
a data output interface module coupled to the receive tuner to accept said second digital data and provide said first digital data, and
a second device coupled to the data output module to accept said first digital data, wherein settings associated with the second device are controlled according to said first digital data.

8. The system of claim 7, wherein said second digital data transmitted by the transmit tuner includes a user ID.

9. The system of claim 8, wherein the receive unit includes a non-volatile memory to store the user ID.

10. The system of claim 9, wherein the receive tuner identifies the channel having said second digital data according to the user ID.

11. The system of claim 7, wherein the first device comprises a plurality of user interface buttons and the first device provides said first digital data responsive to an operation of the plurality of interface buttons.

12. The system of claim 7, wherein the frequency band is an FM broadcast band.

13. The system of claim 7, wherein the frequency band is an AM broadcast band.

14. A system, comprising:
a transmit unit; and
a receive unit,
wherein the transmit unit includes
a first audio interface module configured to accept a first audio signal and to provide a second audio signal,
a data interface module configured to accept a first digital data and to provide second digital data, and
a transmit tuner using a frequency band coupled to the first audio interface module to accept the second audio signal and coupled to the data interface module to accept said second digital data, wherein the transmit tuner identifying a channel comprising a main channel and at least one side channel, and transmitting the audio signal at the main channel and said second digital data at said at least one side channel; and
wherein the receive unit includes
a receive tuner configured to receive a signal corresponding to a plurality of the channels in the frequency band, wherein the receive tuner is operable to identify the channel having said second digital data in said at one side channel and to receive the second audio signal at the main channel and said second digital data at said at least one side channel,
a data output interface module coupled to the Receive tuner to accept the second digital data and provides the first digital data, and
a second audio interface coupled to the receive tuner to accept the second audio signal and to provide the first audio signal.

15. The system of claim 12, wherein said second digital data transmitted by the transmit tuner includes a user ID.

16. The system of claim 15, wherein the receive unit includes a non-volatile memory to store the user ID.

17. The system of claim 16, wherein the receive tuner identifies the channel having said second digital data based on the user ID.

18. The system of claim 12, wherein the first audio interface comprises an audio encryption module wherein the audio encryption module scrambles the first audio signal into the second audio signal using an encryption key and the second audio interface module comprises an audio decryption module wherein the audio decryption module descrambles the second audio signal into the first audio signal using a decryption key.

19. The system of claim 18, wherein the receive unit includes a non-volatile memory to store the decryption key.

20. The system of claim 18, wherein the second digital data provided by the data interface module includes a user ID and a version of decryption key scrambled using the user ID, and the receive unit includes a non-volatile memory to store the user ID and descrambles the scrambled decryption key using the user ID.

21. The system of claim 18, wherein the audio encryption module and the audio decryption module are configured to implement analog audio scrambling.

22. The system of claim 18, wherein the audio encryption module and the audio decryption module are configured implement digital audio scrambling.

23. The system of claim 12, wherein a bandwidth associated with the side channel is wider than a bandwidth associated with the main channel.

24. The system of claim 14, wherein the frequency band is an FM broadcast band.

25. The system of claim 14, wherein the frequency band is an AM broadcast band.

26. A system, comprising:
a transmit unit; and
a receive unit,
wherein the transmit unit includes
a first audio interface module configured to accept a first audio signal and to provide a second audio signal,
a data interface module configured to accept a first digital data and to provide a second digital data, and
a transmit tuner using a frequency band coupled to the first audio interface module to accept the second audio signal and coupled to the data interface module to accept said second digital data, wherein the transmit tuner having a channel condition assessment module to identify a channel comprising a main channel and at least one side channel, and transmitting the audio signal at the main channel and said second digital data at said at least one side channel; and
wherein the receive unit includes
a receive tuner configured to receive a signal corresponding to a plurality of the channels in the frequency band, wherein the receive tuner is operable to identify the channel having said second digital data in said at one side channel and to receive the second audio signal at the main channel and said second digital data at said at least one side channel,
a data output interface module coupled to the receive tuner to accept the second digital data and provides the first digital data, and
a second audio interface coupled to the receive tuner to accept the second audio signal and to provide the first audio signal.

27. The system of claim 24, wherein said second digital data transmitted by the transmit tuner includes a user ID.

28. The system of claim 27, wherein the receive unit includes a second non-volatile memory to store the user ID.

29. The system of claim 28, wherein the receive tuner identifies the channel having said second digital data based on the user ID.

30. The system of claim 24, wherein the first audio interface comprises an audio encryption module wherein the audio encryption module scrambles the first audio signal into the second audio signal using an encryption key and the second audio interface module comprises an audio decryption module wherein the audio decryption module descrambles the second audio signal into the first audio signal using a decryption key.

31. The system of claim 30, wherein the receive unit includes a non-volatile memory to store the decryption key.

32. The system of claim 31, wherein the second digital data provided by the data interface module includes a user ID and a version of decryption key scrambled using the user ID, and the receive unit includes a non-volatile memory to store the user ID and descrambles the scrambled decryption key using the user ID.

33. The system of claim 30, wherein the audio encryption module and the audio decryption module implement analog audio scrambling.

34. The system of claim 30, wherein the audio encryption module and the audio decryption module implement digital audio scrambling.

35. The system of claim 24, wherein a bandwidth associated with the side channel is wider than a bandwidth associated with the main channel.

36. The system of claim 26, wherein the frequency band is an FM broadcast band.

37. The system of claim 26, wherein the frequency band is an AM broadcast.
